(19) United States
(12) Patent Application Publication
(10) Pub. No.: US 2026/0047057 A1
(43) Pub. Date: Feb. 12, 2026

(54) STATIC RANDOM ACCESS MEMORY AND METHOD FOR FABRICATING THE SAME

(71) Applicant: UNITED MICROELECTRONICS CORP., Hsin-Chu City (TW)

(72) Inventor: Chia-Chen Sun, Kaohsiung City (TW)

(73) Assignee: UNITED MICROELECTRONICS CORP., Hsin-Chu City (TW)

(21) Appl. No.: 18/829,208

(22) Filed: Sep. 9, 2024

(30) Foreign Application Priority Data
Aug. 7, 2024 (TW) 113129567

(51) Int. Cl. H10B 10/00

(52) U.S. Cl. CPC H10B 10/12

(57) ABSTRACT

A method for fabricating semiconductor device includes the steps of first forming a gate structure on a substrate and an interlayer dielectric (ILD) layer around the gate structure, transforming the gate structure into a metal gate, forming a hard mask on the metal gate, forming a mask layer on the hard mask as the mask layer includes a first opening directly on the metal gate, forming an inter-metal dielectric (IMD) layer on the mask layer, removing the IMD layer and the mask layer to form a second opening, and then forming a metal layer in the second opening for forming a contact plug. Preferably, the contact plug includes a step profile.

### BACKGROUND OF THE INVENTION

### 1. Field Of The Invention

The invention relates to a method for fabricating static random access memory (SRAM), and more particularly, to a method of forming contact plug on edge area of SRAM.

### 2. Description Of The Prior Art

An embedded static random access memory (SRAM) comprises a logic circuit and a static random access memory connected to the logic circuit. SRAM is a kind of volatile memory cell, which means it preserves data only while power is continuously applied. SRAM is built of cross-coupled inverters that store data during the time that power remains applied, unlike dynamic random access memory (DRAM) that needs to be periodically refreshed. Because of its high access speed, SRAM is also used in computer system as a cache memory.

However, as pitch of the exposure process decreases, contact plugs fabricated in current SRAM devices often have shortcomings such as pitch shrinkage and poor connection. Hence, how to enhance the current SRAM process for improving this issue has become an important task in this field.

### SUMMARY OF THE INVENTION

According to an embodiment of the present invention, a method for fabricating semiconductor device includes the steps of first forming a gate structure on a substrate and an interlayer dielectric (ILD) layer around the gate structure, transforming the gate structure into a metal gate, forming a hard mask on the metal gate, forming a mask layer on the hard mask as the mask layer includes a first opening directly on the metal gate, forming an inter-metal dielectric (IMD) layer on the mask layer, removing the IMD layer and the mask layer to form a second opening, and then forming a metal layer in the second opening for forming a contact plug. Preferably, the contact plug includes a step profile.

According to another aspect of the present invention, a semiconductor device includes a gate structure on a substrate and an interlayer dielectric (ILD) layer around the gate structure and a contact plug on and directly contacting the gate structure. Preferably, the contact plug includes a step profile.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a circuit diagram of a six-transistor SRAM (6T-SRAM) cell of a SRAM of the present invention.

FIG. 2 illustrates a partial layout of a 6T-SRAM according to an embodiment of the present invention.

FIGS. 3-9 illustrate a method for fabricating the 6T-SRAM taken along the sectional line AA′ of FIG. 2

FIG. 10 illustrates a structural view of a semiconductor device according to an embodiment of the present invention.

FIG. 11 illustrates a structural view of a semiconductor device according to an embodiment of the present invention.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “one embodiment,” “an embodiment,” “an example embodiment,” “some embodiments,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to effect such feature, structure or characteristic in connection with other embodiments whether or not explicitly described.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or vias are formed) and one or more dielectric layers.

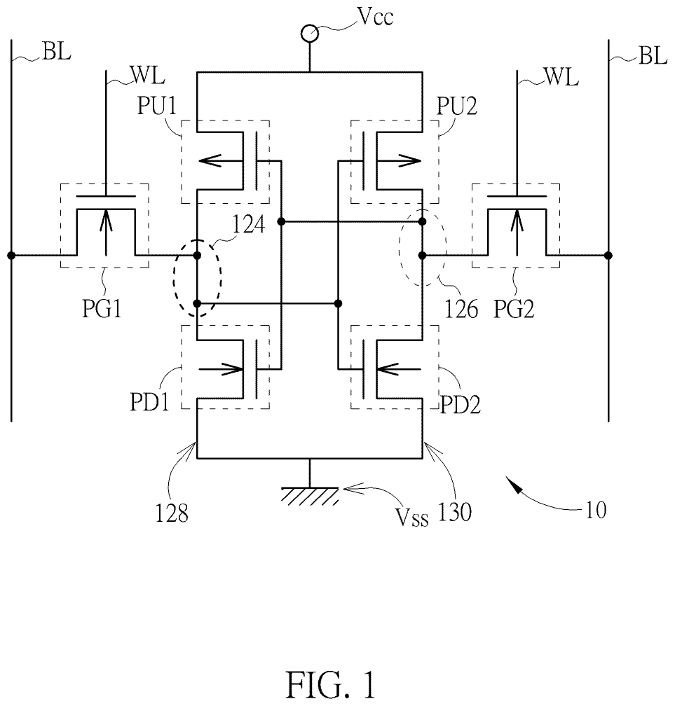

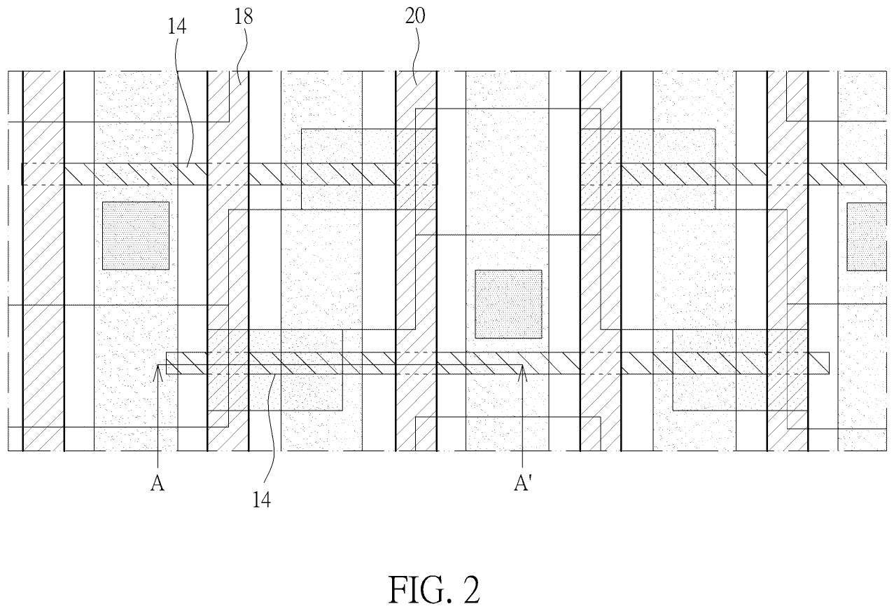

Referring to FIGS. 1-2, FIG. 1 illustrates a circuit diagram of a six-transistor SRAM (6T-SRAM) cell of a SRAM of the present invention and FIG. 2 illustrates a partial layout of the 6T-SRAM according to an embodiment of the present invention. As shown in FIGS. 1-2, the SRAM device of the present invention preferably includes at least one SRAM cell, cach SRAM cell including a six-transistor SRAM (6T-SRAM) cell 10.

In this embodiment, cach 6T-SRAM cell 10 is composed of a first pull-up transistor PU1, a second pull-up transistor PU2, a first pull-down transistor PD1, a second pull-down transistor PD2, a first pass gate transistor PG1 and a second pass gate transistor PG2. These six transistors constitute a set of flip-flops. The first and the second pull-up transistors PU1 and PU2, and the first and the second pull-down transistors PD1 and PD2 constitute a latch that stores data in the storage nodes 24 and 26. Since the first and the second pull-up transistors PU1 and PU2 act as power load devices, they can be replaced by resistors. Under this circumstance, the static random access memory becomes a four-transistor SRAM (4T-SRAM). In this embodiment, the first and the second pull-up transistors PU1 and PU2 preferably share a source/drain region and electrically connect to a voltage source Vcc, the first and the second pull-down transistors PD1 and PD2 share a source/drain region and electrically connect to a voltage source Vss.

Preferably, the first and the second pull-up transistors PU1 and PU2 of the 6T-SRAM cell 10 are composed of p-type metal oxide semiconductor (PMOS) transistors; the first and the second pull-down transistors PD1 and PD2, and first and the second pass gate transistors PG1 and PG2 are composed of n-type metal oxide semiconductor (NMOS) transistors. The first pull-up transistor PU1 and the first pull-down transistor PD1 constitute an inverter, which further form a series circuit 128. One end of the series circuit 128 is connected to a voltage source Vcc and the other end of the series circuit 128 is connected to a voltage source Vss. Similarly, the second pull-up transistor PU2 and the second pull-down transistor PD2 constitute another inverter and a series circuit 130. One end of the series circuit 130 is connected to the voltage source Vcc and the other end of the series circuit 130 is connected to the voltage source Vss.

The storage node 124 is connected to the respective gates of the second pull-down transistor PD2 and the second pull-up transistor PU2. The storage node 124 is also connected to the drains of the first pull-down transistor PD1, the first pull-up transistor PU1, and the first pass gate transistor PG1. Similarly, the storage node 126 is connected to the respective gates of the first pull-down transistor PD1 and first the pull-up transistor PU1. The storage node 126 is also connected to the drains of the second pull-down transistor PD2, the second pull-up transistor PU2, and the second access transistor PG2. The gates of the first and the second pass gate transistors PG1 and PG2 are respectively coupled to a word line (WL), and the sources are coupled to a relative data line (BL).

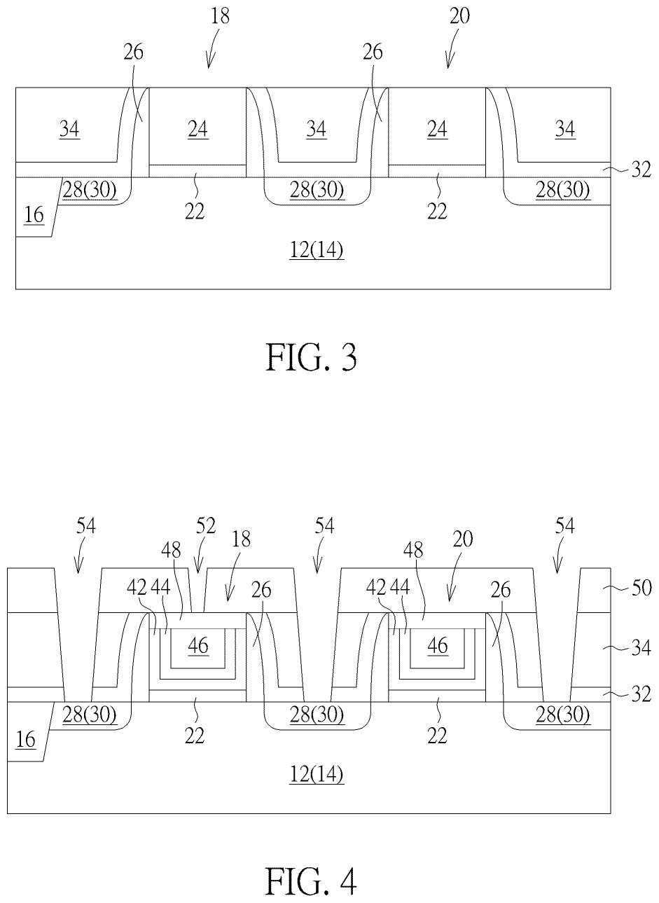

Referring to FIGS. 2-9, FIG. 2 illustrates a layout of a 6T-SRAM according to an embodiment of the present invention and FIGS. 3-9 illustrate a method for fabricating the 6T-SRAM taken along the sectional line AA′ of FIG. 2. As shown in FIGS. 2-3, a substrate 12, such as a silicon substrate or silicon-on-insulator (SOI) substrate is provided, at least a fin-shaped structure 14 is formed on the substrate 12, and the bottom of the fin-shaped structure 14 is surrounded by an insulating layer made of silicon oxide to form a shallow trench isolation (STI) 16. It should be noted that even though this embodiment pertains to a FinFET process, it would also be desirable to apply the process of this embodiment to a non-planar MOS transistor, which is also within the scope of the present invention.

The fin-shaped structure 14 of this embodiment is preferably obtained by a sidewall image transfer (SIT) process. For instance, a layout pattern is first input into a computer system and is modified through suitable calculation. The modified layout is then defined in a mask and further transferred to a layer of sacrificial layer on a substrate through a photolithographic and an etching process. In this way, several sacrificial layers distributed with a same spacing and of a same width are formed on a substrate. Each of the sacrificial layers may be stripe-shaped.

Subsequently, a deposition process and an etching process are carried out such that spacers are formed on the sidewalls of the patterned sacrificial layers. In a next step, sacrificial layers can be removed completely by performing an etching process. Through the etching process, the pattern defined by the spacers can be transferred into the substrate underneath, and through additional fin cut processes, desirable pattern structures, such as stripe patterned fin-shaped structures could be obtained.

Alternatively, the fin-shaped structure 14 of this embodiment could also be obtained by first forming a patterned mask (not shown) on the substrate, 12, and through an etching process, the pattern of the patterned mask is transferred to the substrate 12 to form the fin-shaped structure 14. Moreover, the formation of the fin-shaped structure 14 could also be accomplished by first forming a patterned hard mask (not shown) on the substrate 12, and a semiconductor layer composed of silicon germanium is grown from the substrate 12 through exposed patterned hard mask via selective epitaxial growth process to form the corresponding fin-shaped structure 14. These approaches for forming fin-shaped structure 14 are all within the scope of the present invention.

Next, gate structures of dummy gate such as gate structures 18, 20 are formed on the substrate 12, in which transistors having the gate structures 18, 20 fabricated in later process could be any of the first pull-up transistor PU1, the second pull-up transistor PU2, the first pull-down transistor PD1, the second pull-down transistor PD2, the first pass gate transistor PG1, or the second pass gate transistor PG2 shown in FIG. 1.

In this embodiment, the formation of the gate structures 18, 20 could be accomplished by a gate first process, a high-k first approach from gate last process, or a high-k last approach from gate last process. Since this embodiment pertains to a high-k last approach, a gate dielectric layer 22 or interfacial layer made of silicon oxide, a gate material layer 24 preferably made of polysilicon, and a selective hard mask (not shown) could be formed sequentially on the substrate 12, and a pattern transfer process is then conducted by using a patterned resist (not shown) as mask to remove part of the gate material layer 24 and part of the gate dielectric layer 22 through single or multiple etching processes. After stripping the patterned resist, gate structures 18, 20 composed of a patterned gate dielectric layer 22 and patterned gate material layer 24 are formed on the substrate 12.

Next, at least a spacer 26 is formed on sidewalls of each of the gate structures 18, 20, a source/drain region 28 and epitaxial layers 30 are formed in the fin-shaped structure 14 and/or substrate 12 adjacent to two sides of the spacer 26. In this embodiment, the spacer 26 could be a single spacer or a composite spacer. For instance, the spacer 26 could further include an offset spacer (not shown) and a main spacer (not shown), and the spacer 26 could be selected from the group consisting of SiO₂, SiN, SiON, and SiCN. The source/drain region 28 and epitaxial layers 30 could include different dopants or different materials depending on the type of transistor being fabricated. For instance, the source/drain region 28 could include p-type or n-type dopants and the epitaxial layers 30 could include silicon germanium (SiGe), silicon carbide (SiC), or silicon phosphide (SiP).

Next, a contact etch stop layer (CESL) 32 composed of silicon nitride could be selectively formed on the substrate 52 to cover the gate structures 18, 20, and an interlayer dielectric (ILD) layer 34 is formed on the CESL 32. Next, a planarizing process, such as chemical mechanical polishing (CMP) process is conducted to remove part of the ILD layer 34 and part of the CESL 32 to expose the gate material layer 24 so that the top surfaces of gate material layer 24 and the ILD layer 34 are coplanar.

Next, as shown in FIG. 4, a replacement metal gate (RMG) process is conducted to transform the gate structures 18, 20 into metal gates. For instance, a selective dry etching or wet etching process could be conducted by using etchant including ammonium hydroxide (NH₄OH) or tetramethylammonium hydroxide (TMAH) to remove the gate material layer 24 and even gate dielectric layer 22 in the gate structures 18, 20 for forming recesses (not shown) in the ILD layer 34.

Next, a high-k dielectric layer 42, a work function metal layer 44, and a low resistance metal layer 46 are formed in the recess, and a planarizing process such as CMP is conducted to remove part of low resistance metal layer 46, part of work function metal layer 44, and part of high-k dielectric layer 42 to form metal gates. In this embodiment, the gate structures 18, 20 or metal gates fabricated through high-k last process of a gate last process preferably includes an interfacial layer or gate dielectric layer 22, a U-shaped high-k dielectric layer 42, a U-shaped work function metal layer 44, and a low resistance metal layer 46 as the high-k dielectric layer 42, the work function metal layer 44, and the low resistance metal layer 46 together serving as a gate electrode for each transistor or each device.

In this embodiment, the high-k dielectric layer 42 is preferably selected from dielectric materials having dielectric constant (k value) larger than 4. For instance, the high-k dielectric layer 80 may be selected from hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate (SrBi₂Ta₂O₉, SBT), lead zirconate titanate (PbZrₓTi₁₋ₓO₃, PZT), barium strontium titanate (BaₓSr₁₋ₓTiO₃, BST) or a combination thereof. Preferably, the BBM layer could be selected from the group consisting of TiN and TaN, but not limited thereto.

In this embodiment, the work function metal layer 44 is formed for tuning the work function of the later formed metal gates to be appropriate in an NMOS or a PMOS. For an NMOS transistor, the work function metal layer 44 having a work function ranging between 3.9 cV and 4.3 eV may include titanium aluminide (TiAl), zirconium aluminide (ZrAl), tungsten aluminide (WAl), tantalum aluminide (TaAl), hafnium aluminide (HfAl), or titanium aluminum carbide (TiAlC), but it is not limited thereto. For a PMOS transistor, the work function metal layer 44 having a work function ranging between 4.8 eV and 5.2 eV may include titanium nitride (TiN), tantalum nitride (TaN), tantalum carbide (TaC), but it is not limited thereto. An optional barrier layer (not shown) could be formed between the work function metal layer 44 and the low resistance metal layer 46, in which the material of the barrier layer may include titanium (Ti), titanium nitride (TiN), tantalum (Ta) or tantalum nitride (TaN). Furthermore, the material of the low-resistance metal layer 46 may include copper (Cu), aluminum (Al), titanium aluminum (TiAl), cobalt tungsten phosphide (CoWP) or any combination thereof.

Next, part of the high-k dielectric layer 42, part of the work function metal layer 44, and part of the low resistance metal layer 46 are removed to form a recess (not shown), and a hard mask 48 is then formed into the recess so that the top surfaces of the hard mask 48 and ILD layer 34 are coplanar. The hard mask 48 could be made of material including but not limited to for example SiO₂, SiN, SiON, SiCN, or combination thereof.

Next, a mask layer 50 is formed on the gate structures 18, 20, in which the mask layer 50 includes an opening 52 exposing the gate structure 18 of an edge transistor shown in FIG. 2 but not exposing the gate structure 20 of a middle transistor. Specifically, after a mask layer 50 is formed to cover the gate structures 18, 20, a first photo-etching process is conducted to remove part of the mask layer 50 directly on top of the gate structure 18 or part of the mask layer 50 on the edge portion if viewed under a top view perspective as shown in FIG. 2 for forming an opening 52 exposing the hard mask 48 directly on the gate structure 18. The mask layer 50 directly on top of the gate structure 20 however is not removed during formation of the opening 52. Next, a second photo-etching process is conducted to remove part of the mask layer 50, part of the ILD layer 34, and part of the CESL 32 adjacent to two sides of the gate structures 18, 20 for forming contact holes 54 exposing the source/drain regions 28.

In this embodiment, the width of the opening 52 is less than the width of the low resistance metal layer 46 under a cross-section perspective. Nevertheless, according to other embodiment of the present invention, it would also be desirable to adjust the width of the opening 52 to be greater than the width of the low resistance metal layer 46. For instance, the width of the opening 52 or the edges of the opening 52 could be aligned with left and right sidewalls of the work function metal layer 44 or left and right sidewalls of the gate structure 18 such as left and right sidewalls of the high-k dielectric layer 42, which are all within the scope of the present invention. Preferably, the mask layer 50 is made of tetraethoxysilane (TEOS) and has a thickness between 600-800 Angstroms or most preferably 700 Angstroms.

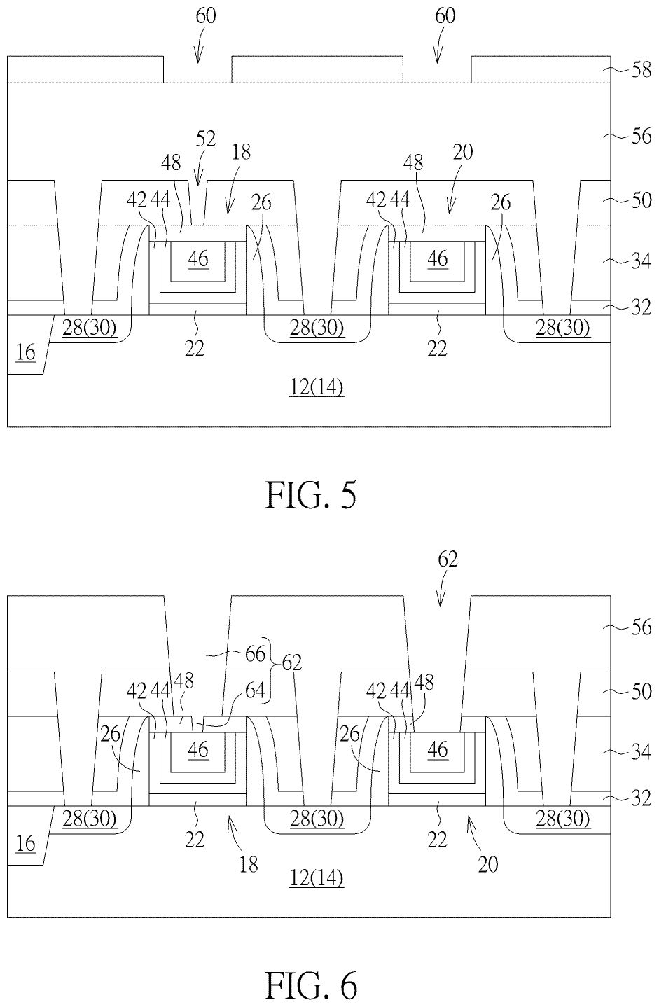

Next, as shown in FIG. 5, an inter-metal dielectric (IMD) layer 56 is formed on the mask layer 50 to fill the opening 52 and the contact holes 54 and then a patterned mask 58 such as patterned resist is formed on the IMD layer 56, in which the patterned mask 58 includes openings 60 exposing the surface of the IMD layer 56 and the width of each opening 60 is greater than the width of the opening 52 formed in the mask layer 50 directly on top of the gate structure 18 as shown in FIG. 4. In this embodiment, the IMD layer 56 preferably includes oxide such as silicon oxide, but could also include an ultra low-k (ULK) dielectric layer including but not limited to for example porous material or silicon oxycarbide (SiOC) or carbon doped silicon oxide (SiOCH).

Next, as shown in FIG. 6, an etching process is conducted by using the patterned mask 58 as mask to remove part of the IMD layer 56, part of the mask layer 50, and part of the hard mask 48 for forming openings 62, and then stripping the patterned mask 58 thereafter. It should be noted that since a smaller opening 52 was already formed in the mask layer 50 directly on top of the gate structure 18 in FIG. 3, more mask layer 50 and less hard mask 48 directly on the gate structure 18 are removed as part of the IMD layer 56, part of the mask layer 50, and part of the hard mask 48 are removed by the etching process so that a width difference is observed between the opening 62 formed in the mask layer 50 and hard mask 48. In other words, the opening 62 formed directly on top of the gate structure 18 preferably includes at least two portions including an opening 64 in the hard mask 48 and another opening 66 in the mask layer 50 and/or IMD layer 56, in which the width of the opening 64 in the hard mask 48 is less than the width of the opening 66 in the mask layer 50 and IMD layer 56 and a step profile is thereby formed as a result of the width difference between the openings 64 and 66. Since no opening 52 is formed in the mask layer 50 directly on top of the gate structure 20, the opening 62 formed by removing part of the IMD layer 56, part of the mask layer 50, and part of the hard mask 48 directly on top of the gate structure 20 at this stage thereby has no step profile. Instead, the opening 62 directly on top of the gate structure 20 only has a single width.

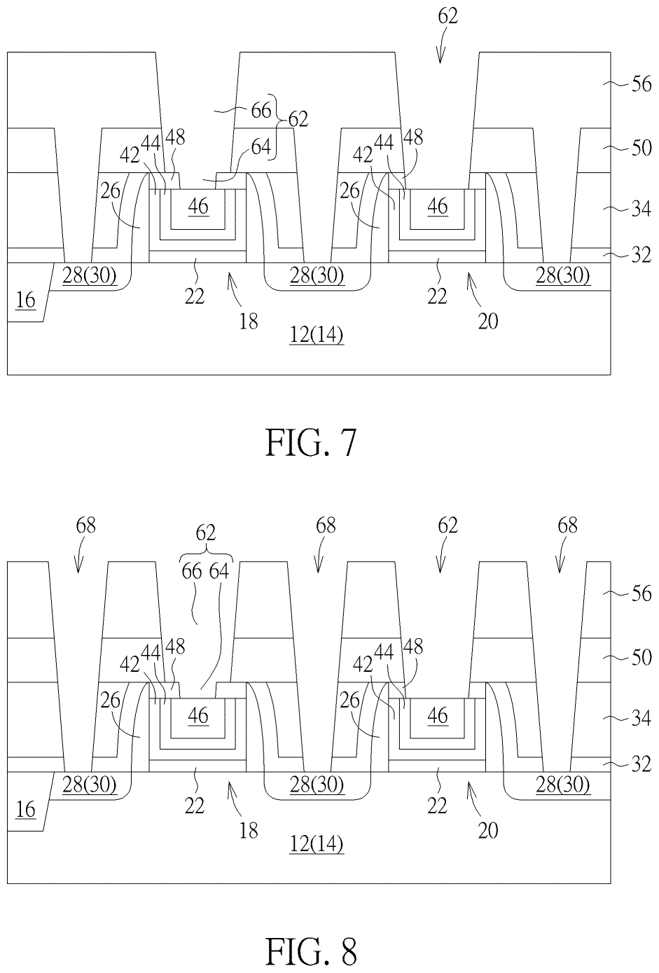

Next, as shown in FIG. 7, another etching process could be conducted with or without using a patterned mask to remove part of the IMD layer 56, part of the mask layer 50, and part of the hard mask 48 once more by extending the aforementioned openings 62. Since the opening 62 directly on top of the gate structure 18 already includes a smaller width opening 64 and a larger width opening 66, the etching process conducted at this stage preferably expands the width of the openings 64 and 66 proportionally.

Next, as shown in FIG. 8, a photo-etching process is conducted by using a patterned mask (not shown) as mask to remove part of the IMD layer 56 adjacent to two sides of the gate structures 18, 20 for forming contact holes 68 exposing the source/drain regions 28 once more.

Next, as shown in FIG. 9, at least a metal layer 70 is formed in the openings 62 and contact holes 68 to form contact plugs 72, 74. In this embodiment, conductive materials including a barrier layer selected from the group consisting of titanium (Ti), titanium nitride (TiN), tantalum (Ta), and tantalum nitride (TaN) and a metal layer 70 selected from the group consisting of tungsten (W), copper (Cu), aluminum (Al), titanium aluminide (TiAl), and cobalt tungsten phosphide (CoWP) could be deposited into the openings 62 and the contact holes 68, and a planarizing process such as CMP is conducted to remove part of aforementioned barrier layer and low resistance metal layer 70 for forming contact plugs 72, 74 electrically connecting the source/drain regions 28 and the gate structures 18, 20. This completes the fabrication of a semiconductor device according to an embodiment of the present invention.

Referring again to FIG. 9, FIG. 9 illustrates a structural view of a semiconductor device according to an embodiment of the present invention. As shown in FIG. 9, the semiconductor device includes at least a gate structure 18 disposed on the substrate 12, an ILD layer 34 around the gate structure 18, a hard mask 48 disposed on the gate structure 18, a mask layer 50 disposed on the hard mask 48, an IMD layer 56 disposed on the mask layer 50, a contact plug disposed directly on the gate structure 18, and another contact plug 72 disposed adjacent to two sides of the gate structure 18 to connect to the source/drain region 28.

In this embodiment, the contact plug 74 directly on top of the gate structure 18 includes a step profile while the contact plugs 72 connecting to the source/drain region 28 adjacent to two sides of the gate structure 18 and the contact plug 74 connecting to the gate structure 20 include only planar and vertical or inclined sidewalls thereby having no step profile whatsoever. Specifically, the contact plug 74 disposed directly on the gate structure 18 includes at least two different widths, in which the width of the contact plug 74 in the hard mask 48 is slightly less than the width of the contact plug 74 in the mask layer 50. Moreover, the bottom surface of the contact plug 74 is even with the top surface of the gate structure 18 or more specifically even with the top surface of the high-k dielectric layer 42, the work function metal layer 44, and low resistance metal layer 46.

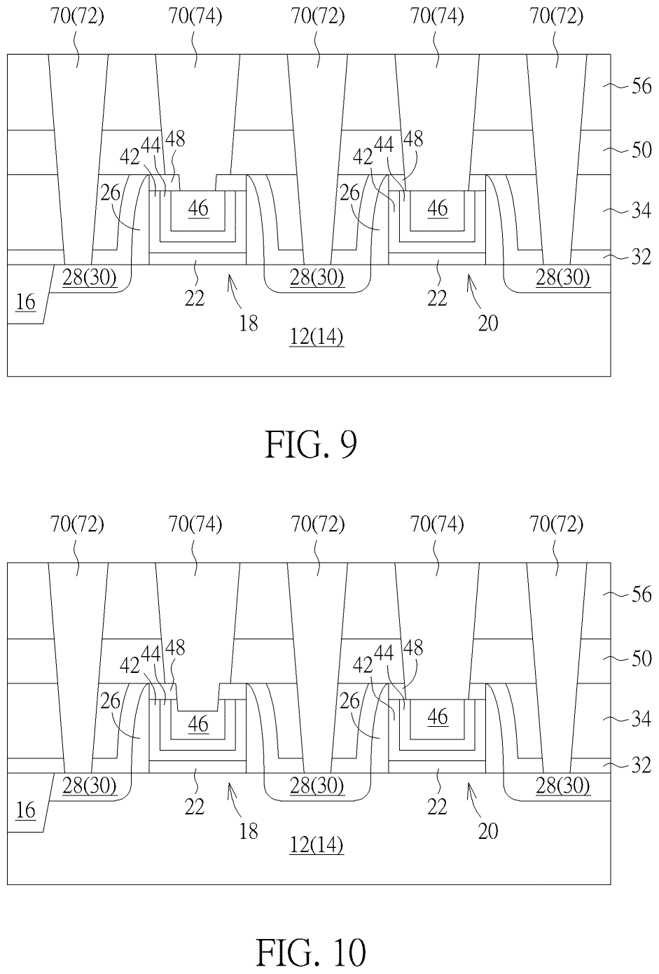

Referring to FIG. 10, FIG. 10 further illustrates a structural view of a semiconductor device according to an embodiment of the present invention. As shown in FIG. 10, in contrast to the bottom surface of the contact plug 74 being even with the top surface of the gate structure 18 as disclosed in FIG. 9, it would also be desirable to slightly lower the bottom surface of the contact plug 74 to be slightly lower than the top surface of the gate structure 18. Specifically, it would be desirable to remove part of the low resistance metal layer 46 and even part of the work function metal layer 44 in the gate structure 18 during expansion of the openings in the mask layer 50 and hard mask 48 in FIGS. 6-7 so that after conductive materials are deposited to form the contact plug 74, the bottom of the contact plug 74 would be extending deeper into part of the low resistance metal layer 46 and/or work function metal layer 44 of the gate structure 18. In other words, the conduct plug 74 directly on top of the gate structure 18 would include two different widths, in which the width of the contact plug 74 in the hard mask 48 and low resistance metal layer 46 is slightly less than the width of the contact plug 74 in the mask layer 50, which is also within the scope of the present invention.

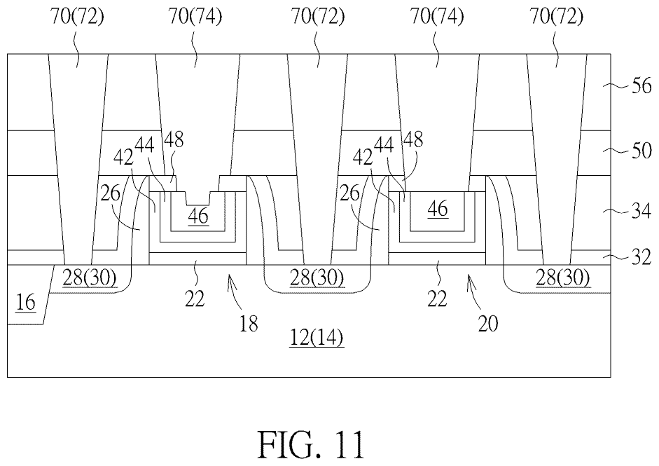

Referring to FIG. 11, FIG. 11 further illustrates a structural view of a semiconductor device according to an embodiment of the present invention. As shown in FIG. 11, it would be desirable to remove part of the low resistance metal layer 46 and even part of the work function metal layer 44 in the gate structure 18 during expansion of the openings in the mask layer 50 and hard mask 48 in FIGS. 6-7 so that after conductive materials are deposited to form the contact plug 74, the bottom of the contact plug 74 would be extending deeper into part of the low resistance metal layer 46 and/or work function metal layer 44 of the gate structure 18.

In contrast to the contact plug 74 extending into the hard mask 48 and low resistance metal layer 46 having same widths as shown in FIG. 10, the contact plug 74 inserting into the hard mask 48 and low resistance metal layer 46 preferably has different widths. In other words, the conduct plug 74 directly on top of the gate structure 18 preferably includes three different widths, in which the width of the contact plug 74 in the low resistance metal layer 46 is less than the width of the contact plug 74 in the hard mask 48 and the width of the contact plug 74 in the hard mask 48 is further less than the width of the contact plug 74 in the mask layer 50, which is also within the scope of the present invention.

Overall, the present invention discloses an approach of forming contact plug connecting transistor on edge area of a SRAM device, which first forms at least a gate structure 18 on a substrate and an ILD layer around the gate structure according to FIGS. 3-4, transforms the gate structure 18 into metal gate, forms a mask layer 50 including an opening 52 directly on top of the metal gate, removes part of the mask layer and ILD layer adjacent to two sides of the metal gate to form contact holes, forms an IMD layer to fill the opening and the contact holes according to FIG. 5, and then conducts at least a photo-etching process to remove part of the IMD layer and mask layer directly on top of the metal gate to form an opening 62 and remove part of the IMD layer adjacent to two sides of the metal gate to form contact holes 68 according to FIGS. 6-7. By first forms an opening or recess in the mask layer directly above the metal gate before defining the pattern of the contact plugs formed afterwards as shown in FIG. 4, the present invention is able to form contact plugs 74 with step profile connecting to metal gate in the later process. Ideally, the utilization of contact plugs 74 with step profiles fabricated by above processes could effectively improve issues such as pitch shrinkage and/or poor connection in current SRAM devices thereby increasing performance and yield of the product substantially.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating semiconductor device, comprising:
forming a gate structure on a substrate and an interlayer dielectric (ILD) layer around the gate structure; and
forming a contact plug on and directly contacting the gate structure, wherein the contact plug comprises a step.

2. The method of claim 1, further comprising:
transforming the gate structure into a metal gate;
forming a hard mask on the metal gate;
forming a mask layer on the hard mask, wherein the mask layer comprises a first opening directly on the metal gate;
forming an inter-metal dielectric (IMD) layer on the mask layer;
removing the IMD layer and the mask layer to form a second opening; and
forming a metal layer in the second opening for forming the contact plug.

3. The method of claim 2, wherein a width of the first opening is less than a width of the second opening.

4. The method of claim 2, further comprising removing the IMD layer, the mask layer, and the hard mask to form a third opening in the hard mask and the second opening in the mask layer and the IMD layer.

5. The method of claim 4, wherein a width of the third opening is less than a width of the second opening.

6. The method of claim 2, wherein the contact plug comprises a first width in the hard mask and a second width in the mask layer.

7. The method of claim 6, wherein the first width is less than the second width.

8. A semiconductor device, comprising:
a gate structure on a substrate and an interlayer dielectric (ILD) layer around the gate structure; and
a contact plug on and directly contacting the gate structure, wherein the contact plug comprises a step.

9. The semiconductor device of claim 8, further comprising:
a hard mask on the gate structure;
a mask layer on the hard mask; and
an inter-metal dielectric (IMD) layer on the mask layer.

10. The semiconductor device of claim 9, wherein the contact plug comprises a first width in the hard mask and a second width in the mask layer.

11. The semiconductor device of claim 10, wherein the first width is less than the second width.

12. The semiconductor device of claim 8, wherein a bottom surface of the contact plug is even with a top surface of the gate structure.

13. The semiconductor device of claim 8, wherein a bottom surface of the contact plug is lower than a top surface of the gate structure.

14. The semiconductor device of claim 8, wherein the gate structure comprises a metal gate.
